(19) United States
(12) Patent Application Publication
(10) Pub. No.: US 2015/0115344 A1
(43) Pub. Date: Apr. 30, 2015

(54) THREE DIMENSIONAL STACKED SEMICONDUCTOR STRUCTURE AND METHOD FOR MANUFACTURING THE SAME

(71) Applicant: MACRONIX INTERNATIONAL CO., LTD., Hsinchu (TW)

(72) Inventor: Erh-Kun Lai, Taichung City (TW)

(73) Assignee: MACRONIX INTERNATIONAL CO., LTD., Hsinchu (TW)

(21) Appl. No.: 14/065,479

(22) Filed: Oct. 29, 2013

(51) Int. Cl. H01L 27/115

(52) U.S. Cl. CPC H01L 27/11597; H01L 27/11578
USPC 257/314; 438/588

(57) ABSTRACT

A 3D stacked semiconductor structure is provided, comprising a plurality of stacks formed on a substrate; at least a contact hole formed vertically in one of the stacks; a conductor formed in the contact hole; and a charging trapping layer at least formed at sidewalls of the stacks. One of the stacks comprises a multi-layered pillar, including a plurality of insulating layers and a plurality of conductive layers arranged alternately, and a dielectric layer formed on the multi-layered pillar. The contact hole is formed vertically in one of the stacks, and the contact hole penetrates the dielectric layer, the insulating layers and the conductive layers of the corresponding stack. Also, a top surface of the conductor is higher than a top surface of the multi-layered pillar for the corresponding stack.

### BACKGROUND

1. Field of the Invention

The disclosure relates in general to a three-dimensional (3D) stacked semiconductor structure and method of manufacturing the same, and more particularly to the 3D stacked semiconductor structure having a conductive strap for source contacts and method of manufacturing the same.

2. Description of the Related Art

A nonvolatile semiconductor memory device is typically designed to securely hold data even when power is lost or removed from the memory device. Various types of nonvolatile memory devices have been proposed in the related art. Also, manufactures have been looking for new developments or techniques combination for stacking multiple planes of memory cells, so as to achieve greater storage capacity. For example, several types of multi-layer stackable NAND-type flash memory structures have been proposed. However, the typical 3D memory structure suffers from several problems.

FIG. 1 is a perspective view of part of a 3D stacked semiconductor structure, in particular, a 3D NAND memory array structure. The 3D stacked semiconductor structure includes an array region 11 and a fan-out region 13. The multilayer array is formed on an insulating layer, and includes a plurality of word lines 125-1 WL, . . . , 125-N WL conformal with the plurality of stacks. The plurality of stacks includes semiconductor strips 112, 113, 114, 115. Semiconductor strips in the same plane are electrically coupled together by stairstep structures, also referred to as bit line structures. Stairstep structures 102B, 103B, 104B, 105B terminate semiconductor 10 strips, such as semiconductor strips 102, 103, 104, 105. As illustrated, these stairstep structures 102B, 103B, 104B, 105B are electrically connected to different bit lines for connection to decoding circuitry to select planes within the array. The stack of semiconductor strips 102, 103, 104, 105 is terminated at one end by the stairstep structures 102B, 103B, 104B, 105B, passes through SSL gate structure 109, ground select line GSL 127, word lines 125-N WL through 125-1 WL, ground select line GSL 126, and terminated at the other end by a source line (obscured by other parts of figure). The stack of semiconductor strips 112, 113, 114, 115 is terminated at one end by the stairstep structures 112A, 113A, 114A, 115A, passes through SSL gate 25 structure 119, ground select line GSL 126, word lines 125-1 WL through 125-N WL, ground select line GSL 127, and terminated at the other end by source line 128.

Take a source line 128 for example. A source line 128 comprises a stack of several insulating layer (ex: oxide layers) and conductive layers (ex: such as polysilicon as gate material) arranged alternately. A contact holes is formed vertically to the stack and filled with conductors for connecting each of the conductive layers to outer circuits. Typically, the conductors filled in the contact holes is formed before bit line (BL) hard mask (HM) (ex: made of a dielectric material) for self-aligned purpose; however, it causes the contact holes refilled by HM material, which is a problem for source contact (SC) pick-up process. Also, a source contact (SC) region of the conventional 3D stacked semiconductor structure is an open area during the word line (WL) etching (ex: by RIE), which suffers more WL loading effect than the cell region. Conventionally, it requires thicker HM in the SC region for protection against the WL etching. Furthermore, the SC contact of the conventional stacked structure is constructed at the same level as BL, which increases the alignment difficulty between the SC and the conducting plug lying over the SC at SC pick-up process.

### SUMMARY

The disclosure relates to a three-dimensional (3D) stacked semiconductor structure and method of manufacturing the same. According to the embodiment, the conductor filled in the contact hole is performed after bit line (BL) hard mask (HM) (ex: made of a dielectric material), and the conductor is constructed at the same level as HM. Also, a conductive strap is formed on the position across the conductors. Therefore, the 3D stacked semiconductor structure of the embodiment possesses a reduced resistance, a solid construction for minimizing the WL loading effect, and reliable electrical characteristics.

According to one embodiment of the present disclosure, a 3D stacked semiconductor structure is provided, comprising a plurality of stacks formed on a substrate; at least a contact hole formed vertically in one of the stacks; a conductor formed in the contact hole and connecting the corresponding conductive layers of the corresponding stack; and a charging trapping layer at least formed at sidewalls of the stacks. One of the stacks comprises a multi-layered pillar, including a plurality of insulating layers and a plurality of conductive layers arranged alternately, and a dielectric layer formed on the multi-layered pillar. The contact hole is formed vertically in one of the stacks, and the contact hole penetrates the dielectric layer, the insulating layers and the conductive layers of the corresponding stack. Also, a top surface of the conductor is higher than a top surface of the multi-layered pillar for the corresponding stack.

According to one embodiment of the present disclosure, a method of forming 3D stacked semiconductor structure is provided, comprising steps of forming a plurality of stacks formed on a substrate, wherein one of the stacks comprising a multi-layered pillar including a plurality of insulating layers and a plurality of conductive layers arranged alternately, and a dielectric layer formed on the multi-layered pillar; forming at least a contact hole vertically in one of the stacks, to penetrate the dielectric layer, the insulating layers and the conductive layers of the corresponding stack; forming a conductor in the contact hole to connect the corresponding conductive layers of said one of the stacks, wherein a top surface of the conductor is higher than a top surface of the multi-layered pillar for said one of the stacks; and forming a charging trapping layer at least at sidewalls of the stacks.

The disclosure will become apparent from the following detailed description of the preferred but non-limiting embodiments. The following description is made with reference to the accompanying drawings.

### BRIEF DESCRIPTION OF THE DRAWINGS

FIG. 1 (prior art) is a perspective view of part of a 3D stacked semiconductor structure.

FIG. 2 is a cross-sectional view of a portion of the source contact region of a 3D stacked semiconductor structure according to the embodiment of the present disclosure.

FIG. 3 illustrates a top view of a portion of a 3D stacked semiconductor structure according to the embodiment of the present disclosure.

FIG. 4A˜FIG. 11A and FIG. 4B˜FIG. 11B illustrate a method for manufacturing a 3D stacked semiconductor structure according to one embodiment of the present disclosure.

FIG. 12 illustrates an alternative way for picking up the source contact.

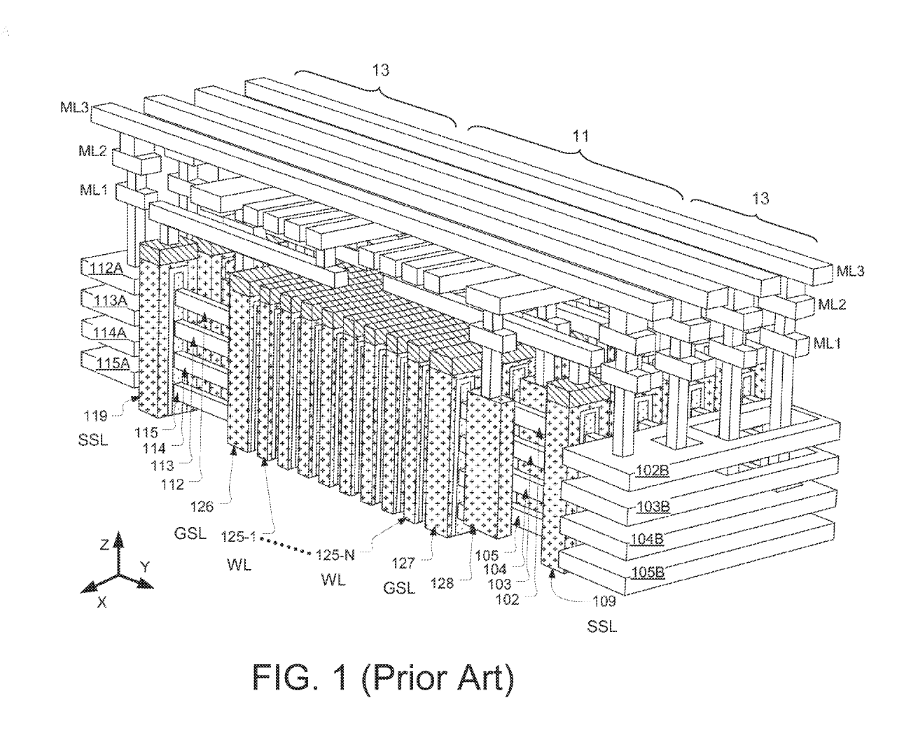

### DETAILED DESCRIPTION

In the embodiments of the present disclosure, a three-dimensional (3D) stacked semiconductor structure and method of manufacturing the same are provided. The 3D stacked semiconductor structure of the embodiment possesses a reduced resistance, a solid construction for minimizing the WL loading effect, and reliable electrical characteristics. Also, the 3D stacked semiconductor structure of the embodiments are manufactured by simple process, and adopting no time-consuming and expensive procedures.

The embodiments of the present disclosure could be implemented in many different applications. For example, the embodiments could be applied to, but not limited to, a 3D flash memory, such as applied in a fan-out region of a 3D NAND flash memory. The embodiments are provided hereinafter with reference to the accompanying drawings for elaborating the 3D stacked semiconductor structures of the disclosure and method of manufacturing the same. However, the present disclosure is not limited thereto. The descriptions disclosed in the embodiments of the disclosure such as detailed structures, manufacturing procedures and material selections are for illustration only, not for limiting the scope of protection of the disclosure.

Also, it is noted that not all embodiments of the invention are shown. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

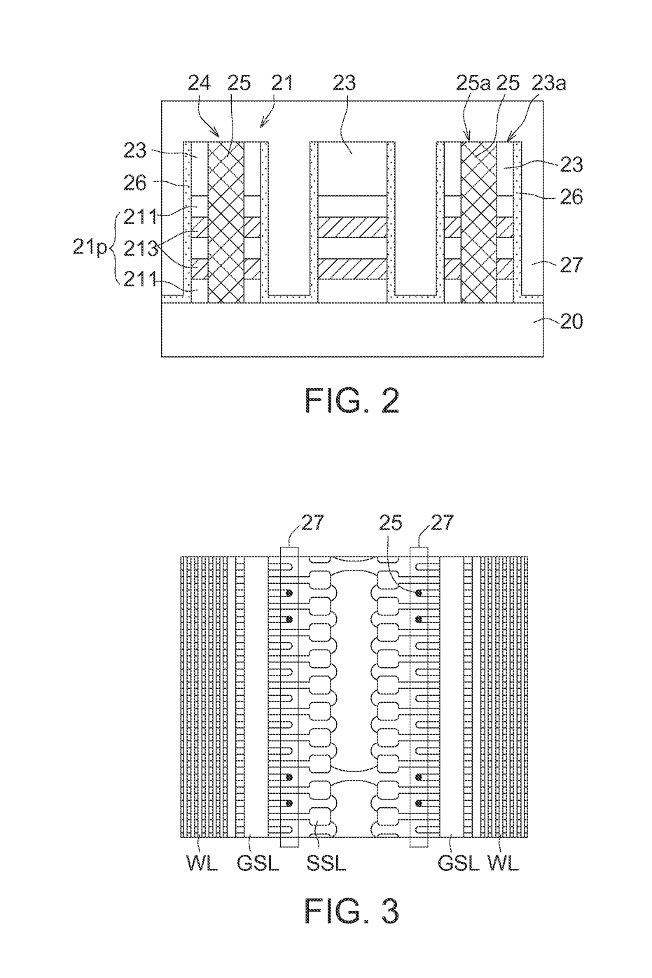

According to the embodiment, the patterning of the source contacts of the 3D stacked semiconductor structures is performed after deposition of the hard mask layer (ex: made of a dielectric material) for bit lines. FIG. 2 is a cross-sectional view of a portion of the source contact region of a 3D stacked semiconductor structure according to the embodiment of the present disclosure. A semiconductor structure comprises a plurality of stacks 21 formed on a substrate 20, and a stack 21 includes a multi-layered pillar 21P and a hard mask layer 23 formed on the multi-layered pillar 21P. The multi-layered pillar 21P comprising a plurality of insulating layers 211 (such as oxide layers) and a plurality of conductive layers 213 (such as polysilicon layers) arranged alternately. The hard mask layer 23 is formed on the top insulating layer 211 of the multi-layered pillar 21P. The hard mask 23 can be made from the dielectric material.

The semiconductor structure also comprises at least a contact hole 24 formed vertically in one of the stacks 21, and the contact hole 24 penetrates the hard mask layer 23, the insulating layers 211 and the conductive layers 213 of the one of the stacks 21. Two contact holes 24 are illustrated in FIG. 2, but the invention is, of course, not limited thereto. Also, a conductor 25 is formed in the contact hole 24, and connects the corresponding conductive layers 213 (which the contact hole 24 extends to) of the stack 21.

The semiconductor structure also comprises a charging trapping layer 26, such as an ONO layer or an ONONO layer, and the charging trapping layer 26 is at least formed at the sidewalls of the stacks 21. As shown in FIG. 2, the charging trapping layer 26 is formed on the sidewalls and the substrate 20, and the top surface 25a of the conductor 25 and the top surface 23a of the hard mask layer 23 are exposed without covering by the charging trapping layer 26.

The conductor 25 functions as a source contact of the 3D stacked semiconductor structure. As shown in FIG. 2, the top surface 25a of the conductor 25 is higher than the top surface of the multi-layered pillar 21P of the stack 21. In one embodiment, the top surface 25a of the conductor 25 is substantially aligned with the top surface 23a of the hard mask layer 23.

According to the embodiment, a conductive strap 27 is further formed on the stacks 21 and contacts the charging trapping layer 26. The conductive strap 27 is formed across the conductors 25 filled in the contact holes 24 of the stacks 21. The conductive strap 27 electrically connects (contacts) the conductors 25 in the contact hole 24 and the charging trapping layer 26 at sidewalls of the stacks 21. FIG. 3 illustrates a top view of a portion of a 3D stacked semiconductor structure according to the embodiment of the present disclosure, which shows a conductive strap 27 formed on the position across the conductors 25 filled in the contact holes 24, and the conductive straps 27 are arranged in parallel with the word lines (WL).

According to the embodiment, the conductive strap 27 is a source contact (SC) strap, which is able to decrease the source contact resistances, In one embodiment, the conductive strap 27 could be simultaneously fabricated with the word lines, by using the same material. Also, the conductive strap 27 is constructed in the SC region, and the source contact (i.e. the conductors 25) is protected by the conductive strap 27 (not by the bit line hard mask), thereby reducing the word line loading effect occurring in the SC region during manufacture, Also, since the SC patterning is performed after the bit line hard mask (HM) deposition, it is hard mask (ex: dielectric material) re-filled free into the source contact.

A manufacturing method of a 3D stacked semiconductor structure of the embodiment is described below. However, it is noted that the details of the structure and manufacturing method of the disclosure are not limited thereto, and could be adjusted and varied according to the requirements of practical applications.

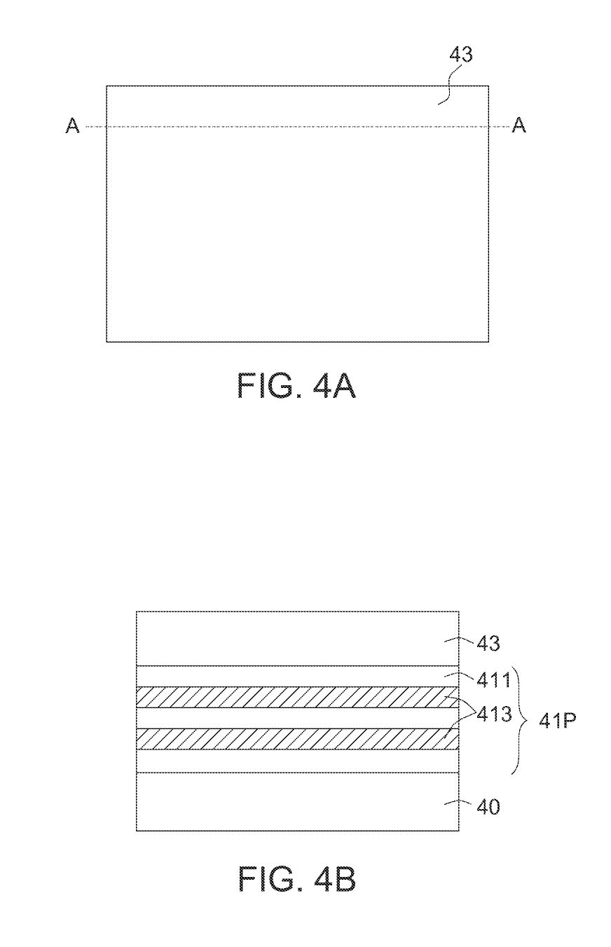

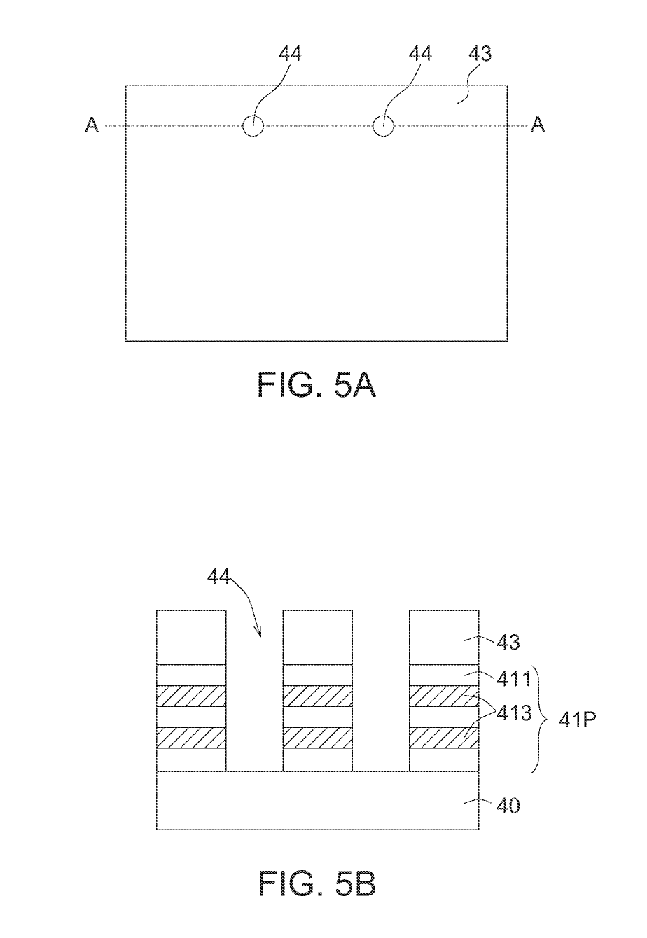

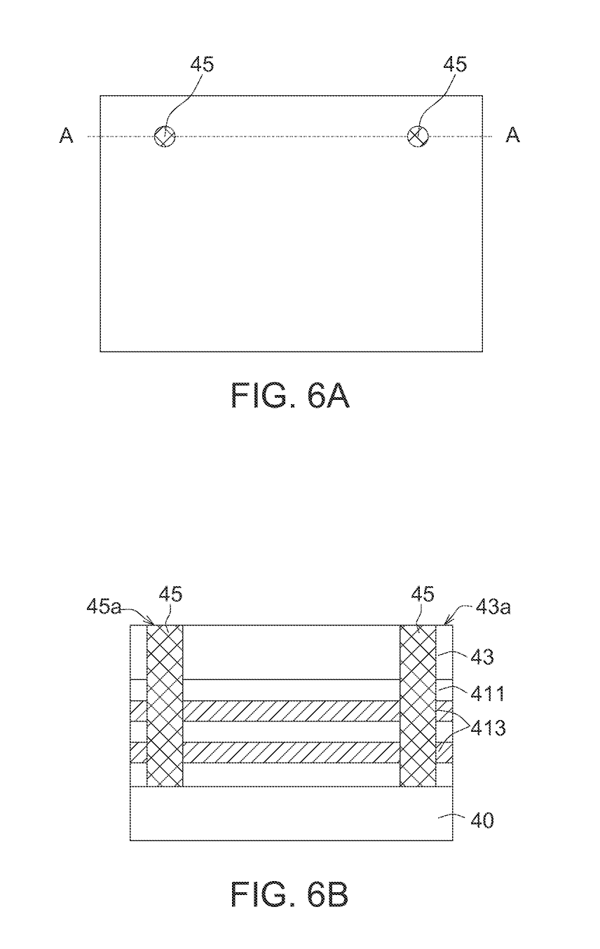

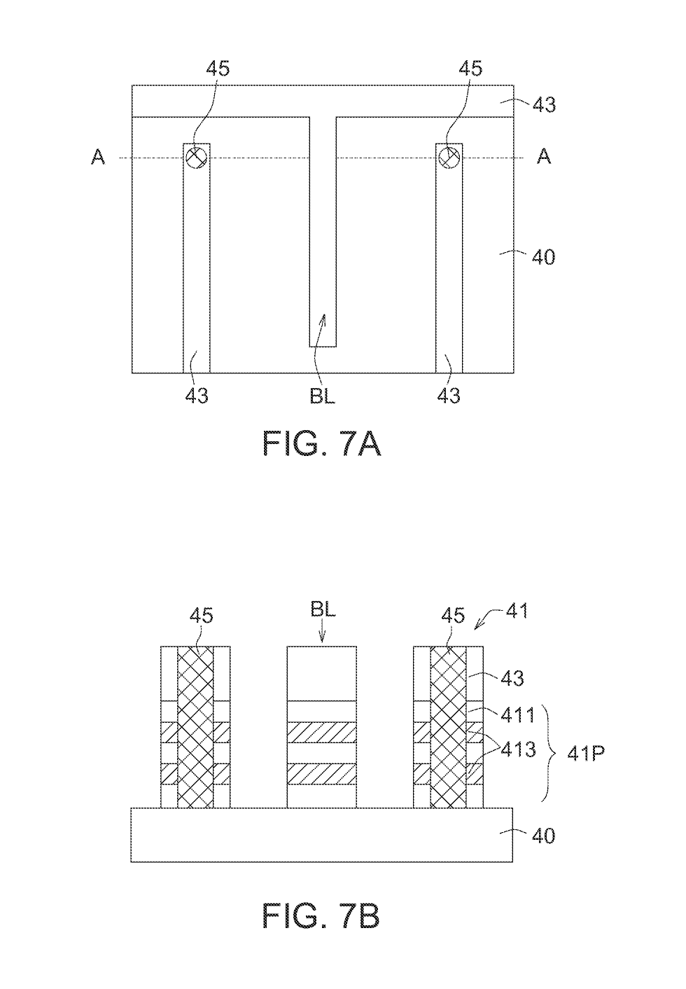

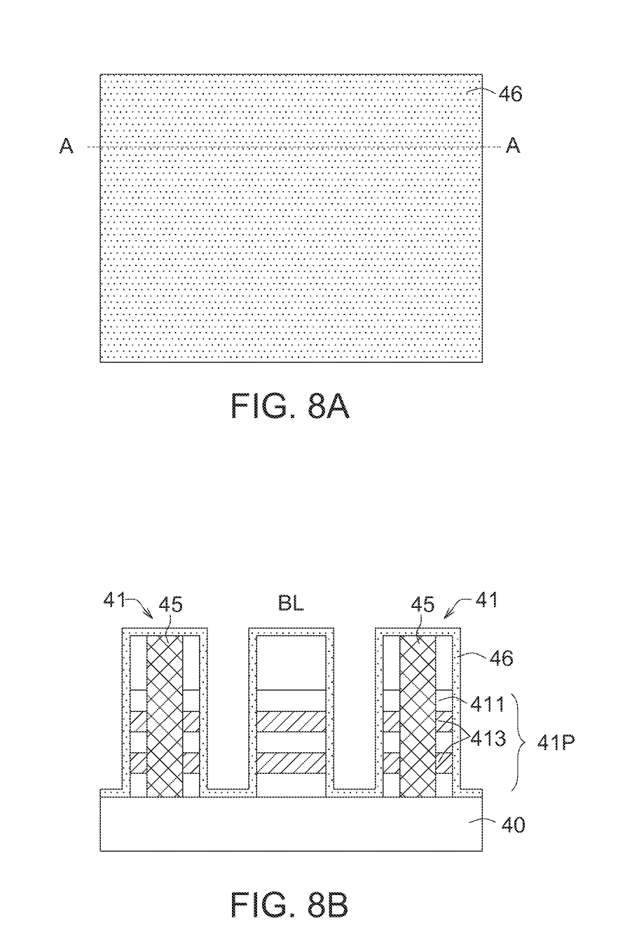

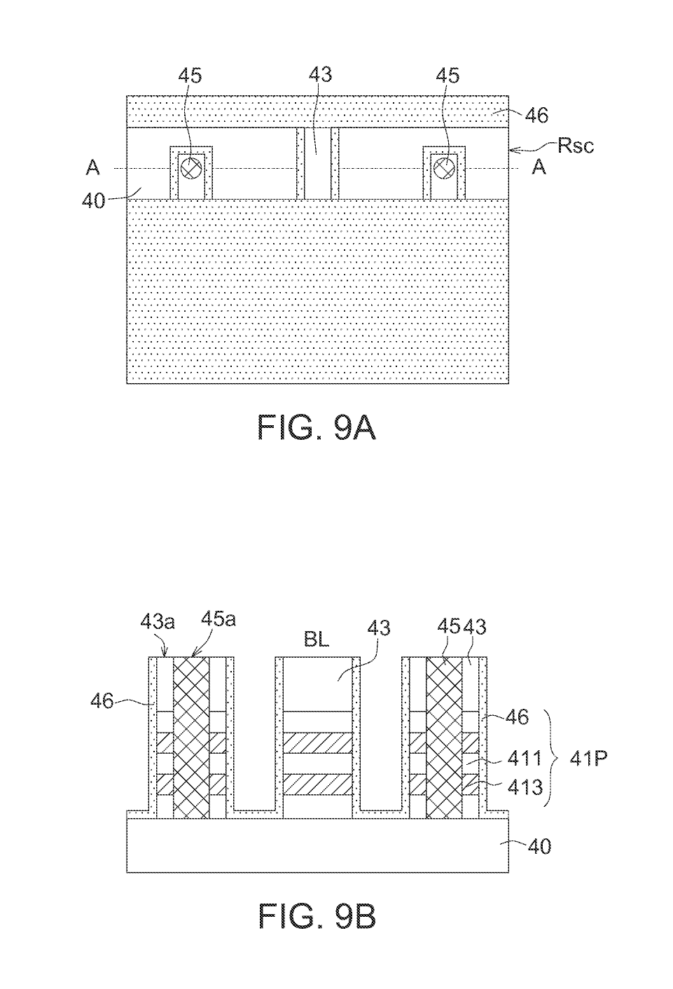

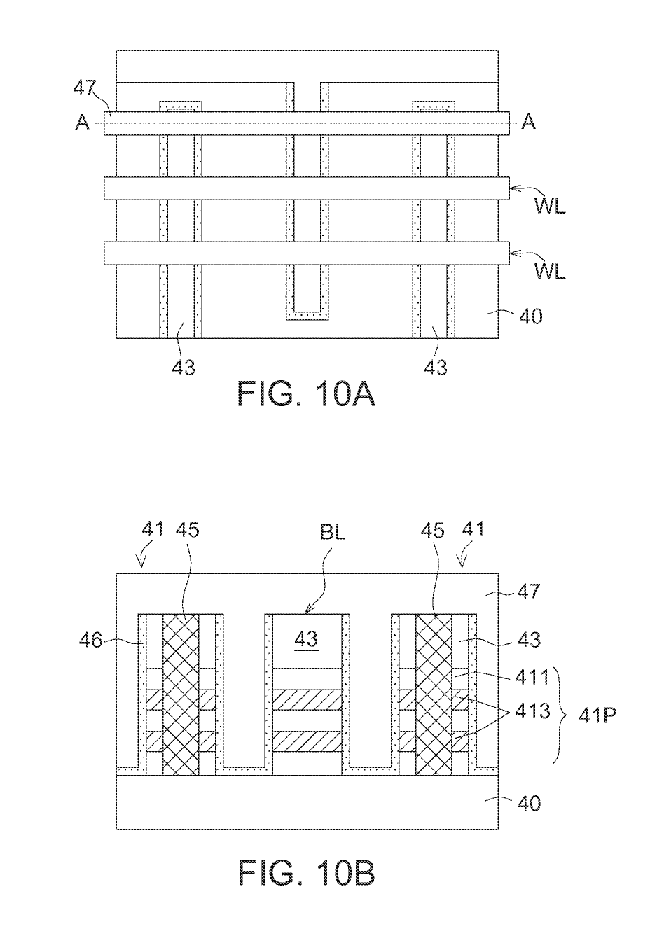

FIG. 4A˜FIG. 11A and FIG. 4B˜FIG. 11B illustrate a method for manufacturing a 3D stacked semiconductor structure according to one embodiment of the present disclosure, Figures labeled with A such as FIGS. 4A, 5A, 6A, . . . 11A show the top views of the 3D stacked semiconductor structure. Figures labeled with B such as FIGS. 4B, 5B, 6B, . . . 11B illustrate cross-sectional views along the cross-sectional lines AA of FIGS. 4A, 5A, 6A, . . . 11A, respectively. The position of the cross-sectional line AA is corresponding to a source contact region.

As shown in FIG. 4A and FIG. 4B, a plurality of insulating layers 411 (such as oxide layers) and a plurality of conductive layers 413 (such as polysilicon layers) are formed alternately on a substrate 40. A hard mask layer 43 is formed on the top insulating layer 411 of the multi-layered pillar 41P. Examples of the material of the hard mask layer 43 include silicon nitride and oxide, deposited on the insulating layer 411.

As shown in FIG. 5A and FIG. 5B, at least a contact hole 44 vertically formed to penetrate the hard mask layer 43, the insulating layers 411 and the conductive layers 413.

After source contact patterning as depicted in FIG. 5A and FIG. 5B, the contact hole 44 is filled with conductive material for constructing a source contact. In one embodiment, a conductive layer (such as made of N+ polysilicon) is deposited on the hard mask layer 43 and fills the contact holes 44, and then planarized to form the conductors 45 in the contact holes 44. In one embodiment, planarization of the conductive layer is performed by chemical mechanical polishing (CMP) or other suitable procedures. As shown in FIG. 6A and FIG. 6B, the top surface 45a of the conductor 45 is substantially aligned with the top surface 43a of the hard mask layer 43. According to the manufacturing method of the embodiment, the top surface 45a of the conductor 45 is higher than the top surface of the top insulating layer 411.

As shown in FIG. 7A and FIG. 7B, the structure of FIG. 6B is then patterned to form the bit lines (BL) and the stacks 41. In one embodiment, the BL hard mask (HM) would not be damaged by using an APF approach for BL patterning. As shown in FIG. 7B, each bit line is formed between the two stacks 41 having source contacts (i.e. the conductors 45), wherein each stack 41 has a multi-layered pillar 41P comprising several insulating layers 411 and the conductive layers 413 arranged alternately, and a hard mask layer 43 formed on the multi-layered pillar 41P. The conductor 45 is filled in the contact hole 44 which vertically penetrates the hard mask layer 43, the insulating layers 411 and the conductive layers 413 of the stack 41.

Then, a charging trapping layer 46 (such as an ONO layer or an ONONO layer) is formed at least at the sidewalls of the stacks 41 and the bit line (BL). Different procedures can be applied to form this structural feature, such as procedures depicted in FIG. 8B and FIG. 9B.

As shown in FIG. 8A and FIG. 8B, a charging trapping layer 46 (such as an ONO layer or an ONONO layer) is deposited to cover the stacks 41, the bit lines (BL) and the substrate 40. Then, part (such as the top portion) of the charging trapping layer 46 is removed for exposing the top surfaces 45a of the conductors 45, the top surfaces of the bit lines (BL), and the top surface 43a of the hard mask layer 43, as shown in FIG. 9A and FIG. 9B. In one embodiment, a lithography procedure on a photo-resist can be applied (but not limitedly) to open the source contact region Rsc, and only the top portions of the charging trapping layer 46 corresponding to the source contact region Rsc are removed, as shown in FIG. 9A. The areas outside the source contact region Rsc are still covered by the charging trapping layer 46. In another embodiment, no photo-resist is adopted, and the top portions of the charging trapping layer 46 on all of the stacks 41 and the bit lines (BL) can be removed. The disclosure has no particular limitation for the procedure herein. The charging trapping layer 46 can be removed by RIE (Reactive-Ion Etching) to expose the conductor 45 in the contact hole 44. Also, an ODL (organic dielectric layer)/SHB approach can be implemented for exposure of the conductor 45 to overcome the topology height.

Afterward, a conductive strap 47 is formed on and across the stacks 41 (as shown in FIG. 3) and in the source contact region Rsc. As shown in FIG. 10A and FIG. 10B, the conductive strap 47 and a plurality of word lines (WLs) can be simultaneously formed on the stacks 41 and the bit lines (BL). Thus, the conductive strap 47 and the word lines (WLs) can be made of the same material in this embodiment. In one embodiment, the conductive strap 47 and the WLs comprise polysilicon (by salicide process). However, it is noted that materials of the conductive strap 47 and the WLs could be the same or different, which are not limited particularly. Materials of the conductive strap 47 and the WLs could be selected according to the actual needs of the practical application.

As shown in FIG. 10A, the conductive strap 47 is disposed in parallel with the word lines (WLs), and the conductive strap 47 and the WLs are spaced apart from each other. As shown in FIG. 10B, the conductive strap 47 electrically connects the conductor 45 in the contact hole 44 (ex: contacts the top surface 45a of the conductor 45) and the charging trapping layer 46. The conductive strap 47 also contacts the top surface 43a of the hard mask layer 43.

Afterward, a conducting portion is formed on the conductive strap 47 for picking up the signals from the source contact (i.e. the conductor 45), which the conducting portion is spaced apart from the conductor 45 and the hard mask layer 43. The conducting portion can be a conductive line or conductive plugs.

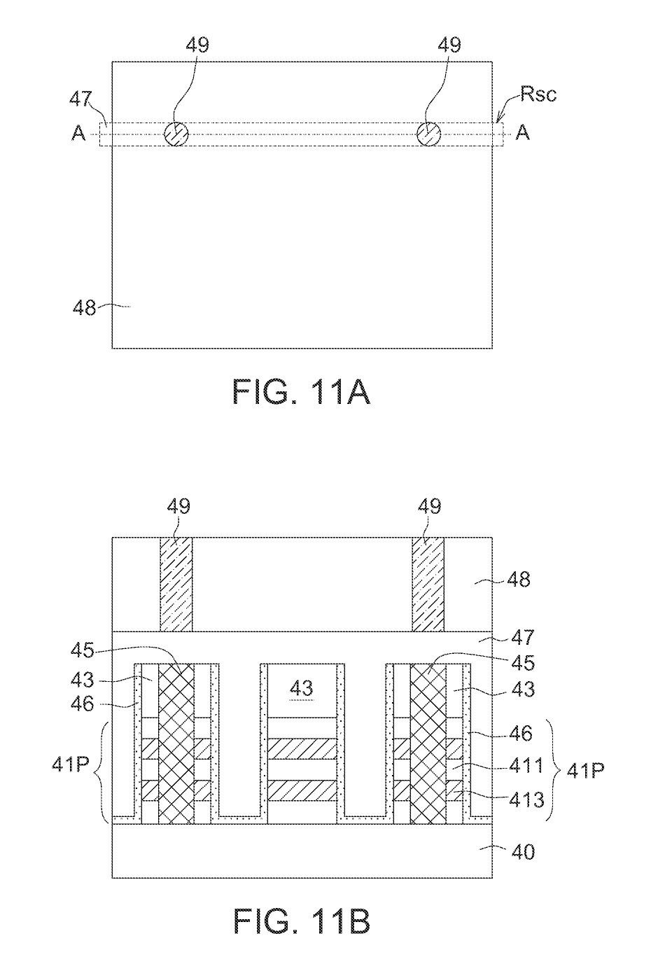

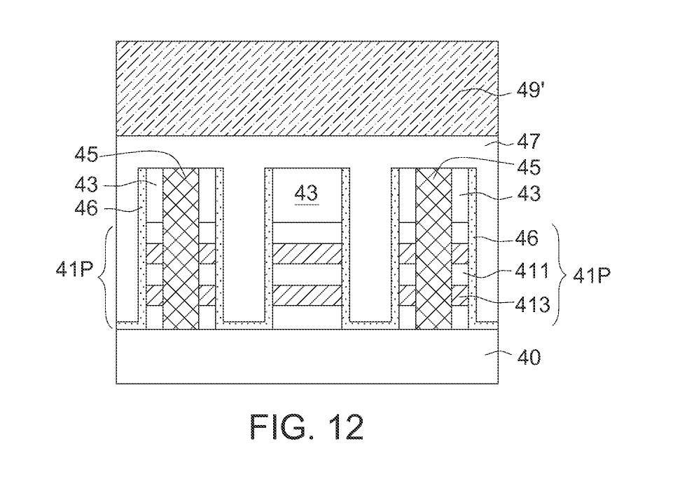

As shown in FIG. 11A and FIG. 11B, an isolating layer 48 (i.e. inter-layer dielectric, ILD) is formed on the conductive strap 47. Several opening holes are formed to penetrate the isolating layer 48, and a conductive material such as tungsten is filled into the opening holes. As shown in FIG. 11B, the conductive plugs 49 in the opening holes of the isolating layer 48 are formed, wherein the conductive plugs 49 electrically connect the conductors 45 in the contact holes 44 through the conductive strap 47. Alternatively, as shown in FIG. 12, which illustrates an alternative way for picking up the source contact, the conducting portion is a conductive line 49′ formed on the conductive strap 47 and across the stacks 41. The conductive line 49′ can comprise tungsten, or material same as the word line.

According to the construction of the embodiment (i.e. the conductor 45, the conductive strap 47 and the conducting portion 49/49′), there is no considerable issue about the misalignment between the conducting plugs and the source contacts. Thus, the 3D stacked semiconductor structure of the embodiment possesses reliable electrical characteristics.

According to the embodiments above, the patterning of the source contacts of the 3D stacked semiconductor structures is performed after the bit line hard mask (HM) (ex: made of a dielectric material) deposition, it is HM re-filled free into the source contact. Also, the conductors 25/45 protruded from the multi-layered pillar 21P/41P functions as a source contact (SC), which is higher than the conventional source contact, thereby decreasing the source contact resistances. Furthermore, the conductive strap 27/47 is constructed in the SC region, and the source contact (i.e. the conductors 25/45) is protected by the conductive strap 27/47 (not protected by the bit line hard mask), thereby reducing the word line loading effect occurring in the SC region during manufacture. Also, the conductive strap 27/47 could be simultaneously fabricated with the word lines by using the same material, which is a time-saving manufacturing process and suitable for mass production.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A 3D stacked semiconductor structure, comprising:
a plurality of stacks formed on a substrate, and one of the stacks comprising:
a multi-layered pillar comprising a plurality of insulating layers and a plurality of conductive layers arranged alternately;
a dielectric layer formed on the multi-layered pillar;
at least a contact hole formed vertically in said one of the stacks, and the contact hole penetrating the dielectric layer, the insulating layers and the conductive layers of said one of the stacks;
a conductor formed in the contact hole and connecting the conductive layers of said corresponding one of the stacks; and
a charging trapping layer at least formed at sidewalls of the stacks;
wherein a top surface of the conductor is higher than a top surface of the multi-layered pillar for said corresponding one of the stacks.

2. The 3D stacked semiconductor structure according to claim 1, further comprising a conductive strap formed on the stacks and contacts the charging trapping layer.

3. The 3D stacked semiconductor structure according to claim 2, wherein the conductive strap electrically connects the conductor in the contact hole.

4. The 3D stacked semiconductor structure according to claim 2, wherein the conductive strap contacts the top surface of the conductor and a top surface of the dielectric layer.

5. The 3D stacked semiconductor structure according to claim 2, further comprising a plurality of word lines arranged on the stacks, and the conductive strap is disposed in parallel with the word lines.

6. The 3D stacked semiconductor structure according to claim 5, wherein the conductive strap and the word lines comprise the same material.

7. The 3D stacked semiconductor structure according to claim 2, further comprising a conducting portion formed on the conductive strap, wherein the conducting portion is spaced apart from the conductor and the dielectric layer.

8. The 3D stacked semiconductor structure according to claim 7, wherein the conducting portion is a conductive line formed on the conductive strap and across the stacks.

9. The 3D stacked semiconductor structure according to claim 2, further comprising:
an isolating layer formed on the conductive strap; and
at least one conductive plug formed in the isolating layer and penetrating the isolating layer,
wherein the conductive plug electrically connects the conductor in the contact hole through the conductive strap.

10. The 3D stacked semiconductor structure according to claim 2, comprising several said contact holes and conductors formed in said stacks correspondingly, wherein the conductive strap is formed across the conductors filled in the contact holes of the stacks.

11. A method of manufacturing a 3D stacked semiconductor structure, comprising:
forming a plurality of stacks formed on a substrate, and one of the stacks comprising:
a multi-layered pillar comprising a plurality of insulating layers and a plurality of conductive layers arranged alternately;
a dielectric layer formed on the multi-layered pillar;
forming at least a contact hole vertically in said one of the stacks, to penetrate the dielectric layer, the insulating layers and the conductive layers of said one of the stacks;
filling a conductor in the contact hole to connect the corresponding conductive layers of said one of the stacks; wherein a top surface of the conductor is higher than a top surface of the multi-layered pillar for said corresponding one of the stacks; and
forming a charging trapping layer at least at sidewalls of the stacks.

12. The method according to claim 11, further comprising forming a conductive strap on the stacks, wherein the conductive strap electrically connects the conductor in the contact hole and the charging trapping layer.

13. The method according to claim 12, wherein the conductive strap contacts the top surface of the conductor and a top surface of the dielectric layer.

14. The method according to claim 12, further comprising forming a plurality of word lines on the stacks and spaced apart from each other, wherein the conductive strap is disposed in parallel with the word lines.

15. The method according to claim 14, wherein the conductive strap and the word lines are made of the same material.

16. The method according to claim 12, further comprising forming a conducting portion on the conductive strap, wherein the conducting portion is spaced apart from the conductor and the dielectric layer.

17. The method according to claim 16, wherein the conducting portion is a conductive line formed on the conductive strap and across the stacks.

18. The method according to claim 12, further comprising:
forming an isolating layer on the conductive strap;
forming at least one opening hole penetrating the isolating layer; and
forming a conductive plug in the opening hole of the isolating layer,
wherein the conductive plug electrically connects the conductor in the contact hole through the conductive strap.

19. The method according to claim 12, comprising forming several said contact holes and conductors in said stacks correspondingly, wherein the conductive strap is formed across the conductors filled in the contact holes of the stacks.

20. The method according to claim 11, the step of forming the charging trapping layer at least at sidewalls of the stacks comprising:
depositing the charging trapping layer on the stacks and the substrate; and
removing part of the charging trapping layer for exposing the top surface of the conductor and a top surface of the dielectric layer.
